(19) United States
(12) Patent Application Publication
(10) Pub. No.: US 2025/0318199 A1
(43) Pub. Date: Oct. 9, 2025

(54) SEMICONDUCTOR DEVICE AND METHOD FOR FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Rachit Dobhal, Taipei City (TW); Jih-Chao CHIU, New Taipei City (TW); Yuan-Ming LIU, Taichung City (TW); Yu-Shan WU, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/625,833

(22) Filed: Apr. 3, 2024

(51) Int. Cl. H01L 29/786; H01L 29/66; H01L 29/78

(52) U.S. Cl. CPC H10D 30/6755; H10D 30/031; H10D 30/6713; H10D 30/701

(57) ABSTRACT

A semiconductor device includes a substrate. An oxide semiconductor channel layer is over the substrate. A gate structure is over the oxide semiconductor channel layer. The gate structure includes an oxide semiconductor barrier layer over the oxide semiconductor channel layer, a gate dielectric layer over the oxide semiconductor barrier layer, and a gate metal over the gate dielectric layer. Source/drain electrodes are in contact with opposite ends of the oxide semiconductor channel layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 15C illustrate a method in various stages of forming a semiconductor device in accordance with some embodiments of the present disclosure.

FIG. 16 shows a simulation result of a semiconductor device in accordance with some embodiments of the present disclosure.

FIG. 17 illustrates a method of forming a semiconductor device in accordance with some embodiments of the present disclosure.

FIG. 18 illustrates a cross-sectional view of an integrated circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

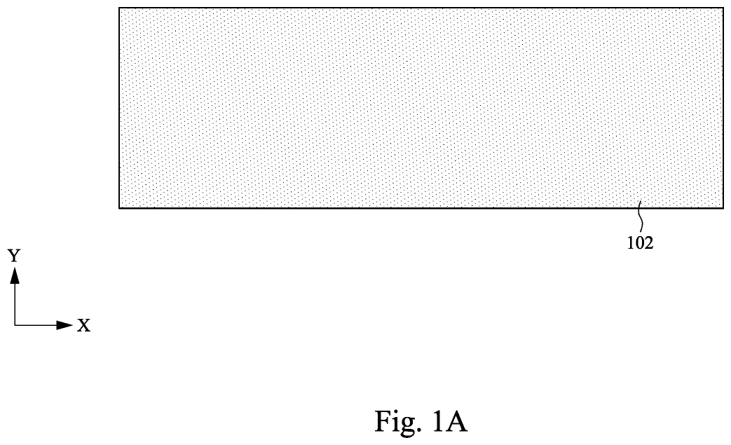

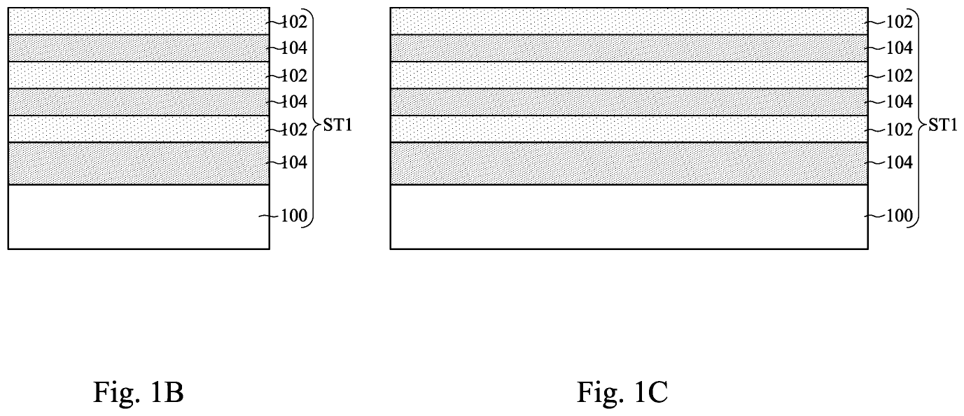

FIGS. 1A to 15C illustrate a method in various stages of forming a semiconductor device in accordance with some embodiments of the present disclosure. In greater detail, FIGS. 1A to 15A are top view of a semiconductor device. FIGS. 1B to 15B are cross-sectional views along line B-B of FIGS. 1A to 15A, respectively. FIGS. 1C to 15C are cross-sectional views along line C-C of FIGS. 1A to 15A, respectively. Although FIGS. 1C to 15C are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. Although the embodiments of the present disclosure are discussed with respect to a gate-all-around (GAA) transistor, embodiments of the present disclosure can also be applied to a nanosheet transistor, a nanowire transistor, a treeFET, a fork-sheet transistor, or the like.

Reference is made to FIGS. 1A, 1B, and 1C. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

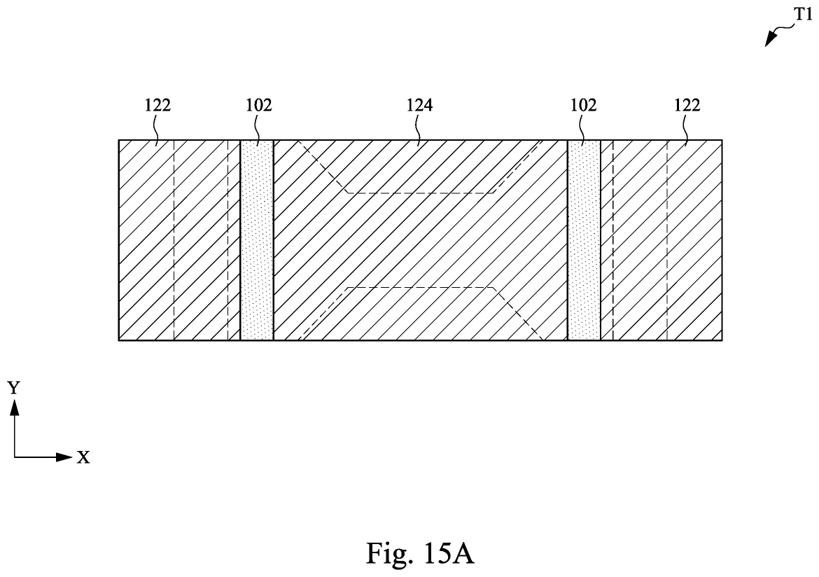

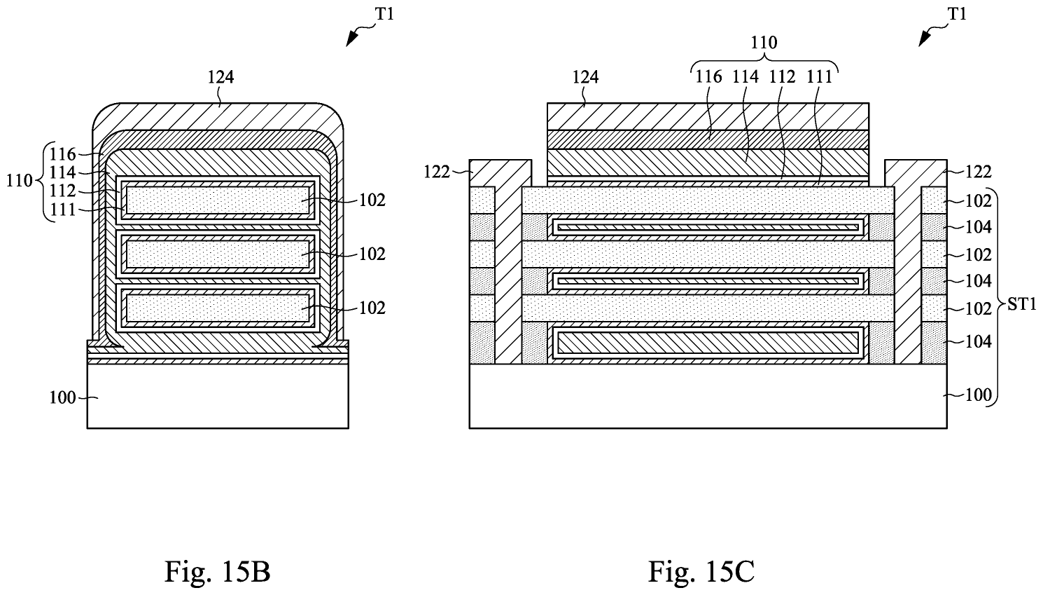

The substrate 100 may also include a front-end-of-line (FEOL) structure, a middle-end-of-line (MEOL) structure over the FEOL structure, and a back-end-of-line (BEOL) structure over the MEOL structure. The FEOL generally encompasses processes related to fabricating IC devices, such as transistors. For example, FEOL processes may include forming isolation features, gate structures, and source and drain features (generally referred to as source/drain features). The MEOL generally encompasses processes related to fabricating contacts to conductive features (or conductive regions) of the IC devices, such as contacts to the gate structures and/or the source/drain features. BEOL generally encompasses processes related to fabricating interconnect structures that interconnect IC features fabricated by FEOL processes (referred to herein as FEOL features or structures) and MEOL processes (referred to herein as MEOL features or structures), thereby enabling operation of the IC devices. For example, BEOL processes may include forming multilayer interconnect features that facilitate operation of the IC devices. In some embodiments, the structure formed through FIGS. 1A to 15C (e.g., the semiconductor device T1 of FIGS. 15A to 15C) may be formed in the BEOL structure.

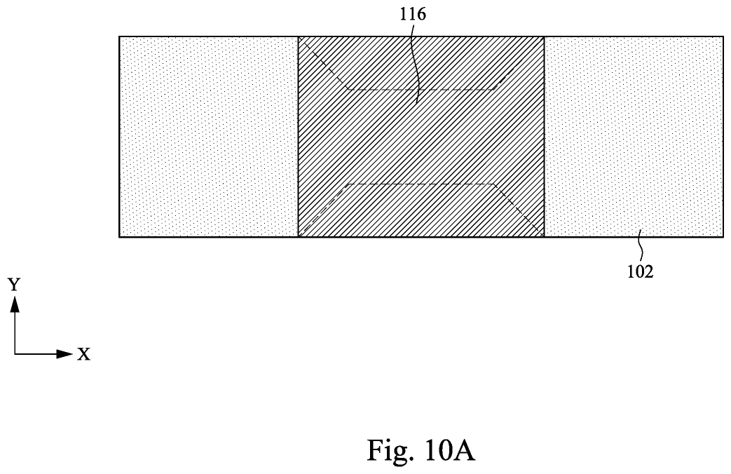

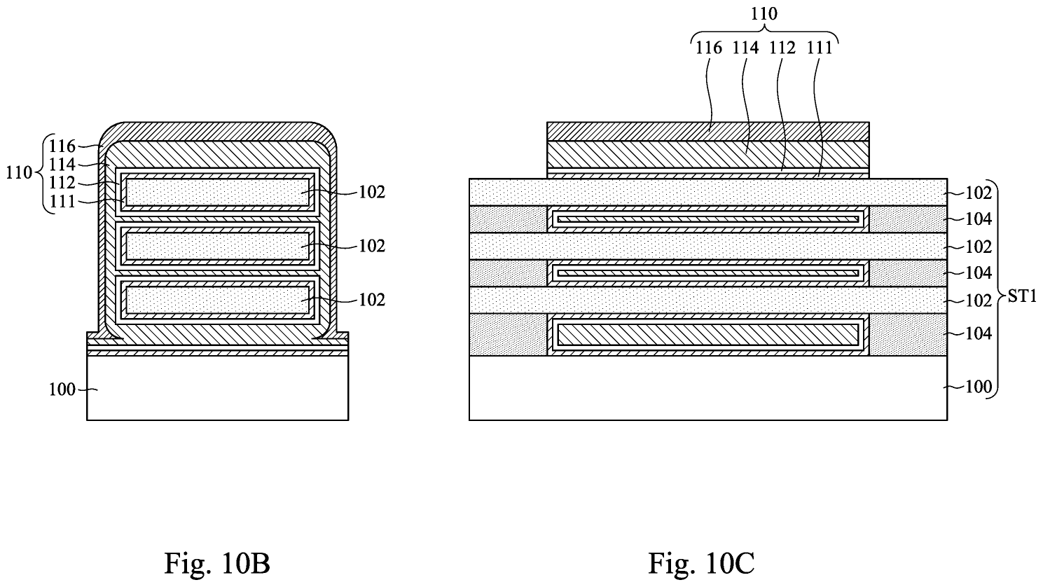

A stack ST1 is formed over the substrate 100. The stack ST1 includes alternating channel material layers 102 and sacrificial layers 104. The channel material layers 102 and the sacrificial layers 104 may be formed using deposition process, such as atomic layer deposition (ALD) process, sputtering, plasma-enhanced chemical vapor deposition (PECVD) process, epitaxial growth, or other suitable deposition process. In some embodiments, portions of the sacrificial layers 104 may be removed during the following gate formation process, and portions of the sacrificial layers 104 may be removed during the following source/drain contact formation process. In some embodiments, each of the channel material layers 102 may include a channel region 102CH and source/drain regions 102SD on opposite sides of the channel region 102CH. Here, the channel region 102CH may be the portion of the channel material layer 102 that are overlapped with a gate structure (e.g., the gate structure 110 in FIGS. 10A to 10C). The source/drain regions 102SD may be the portions of the channel material layer 102 on opposite sides of the channel region 102CH that are not overlapped with the gate structure.

In some embodiments, the channel material layers 102 may include semiconductor material, such as oxide semiconductor material. Examples of oxide semiconductor material include indium gallium zinc oxide (IGZO), indium oxide (InOₓ), zinc oxide (ZnO), indium gallium oxide (IGO), indium zinc oxide (IZO). The channel material layers 102 may also include indium tin oxide (InSnO), tungsten-doped indium oxide (InWO), gallium oxide (GaOₓ), and the like. In other embodiments, the channel material layers 102 may include semiconductor material, such as silicon (Si), germanium (Ge), silicon germanium (SiGe), germanium tin (GeSn), or the like. In some embodiments, the thickness of each channel material layer 102 is in a range from about 1 nm to about 1000 nm. The channel material layers 102 may be formed using suitable deposition process, such as atomic layer deposition (ALD), sputtering, plasma enhanced chemical vapor deposition (PECVD), epitaxy deposition, or other suitable deposition process. In some embodiments, the channel material layers 102 may include amorphous structure.

The sacrificial layers 104 may include material different from the material of the channel material layers 102 to provide sufficient etching selectivity. In some embodiments where the channel material layers 102 are made of oxide semiconductor material, the sacrificial layers 104 may include dielectric material, such as silicon nitride (SiN), silicon oxide (SiOₓ), or the like. In some embodiments where the channel material layers 102 are made of oxide semiconductor material, the sacrificial layers 104 may also include conductive material, such as titanium nitride (TiN), tungsten (W), titanium (Ti), or the like. In some embodiments, the thickness of each sacrificial layer 104 is in a range from about 1 nm to about 1000 nm. The c sacrificial layers 104may be formed using suitable deposition process, such as atomic layer deposition (ALD), sputtering, plasma enhanced chemical vapor deposition (PECVD), epitaxy deposition, or other suitable deposition process.

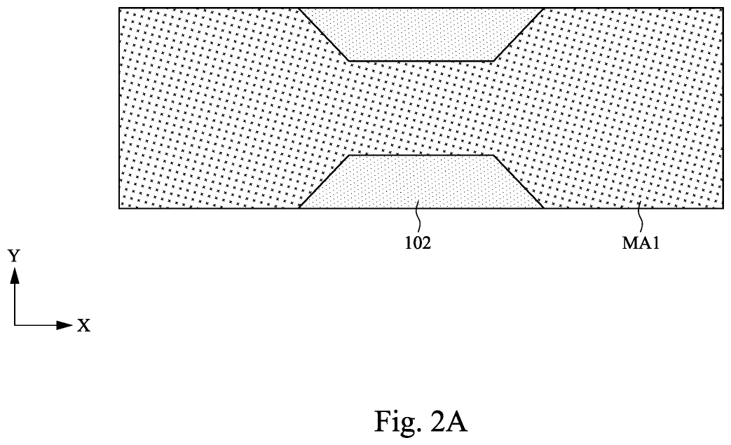

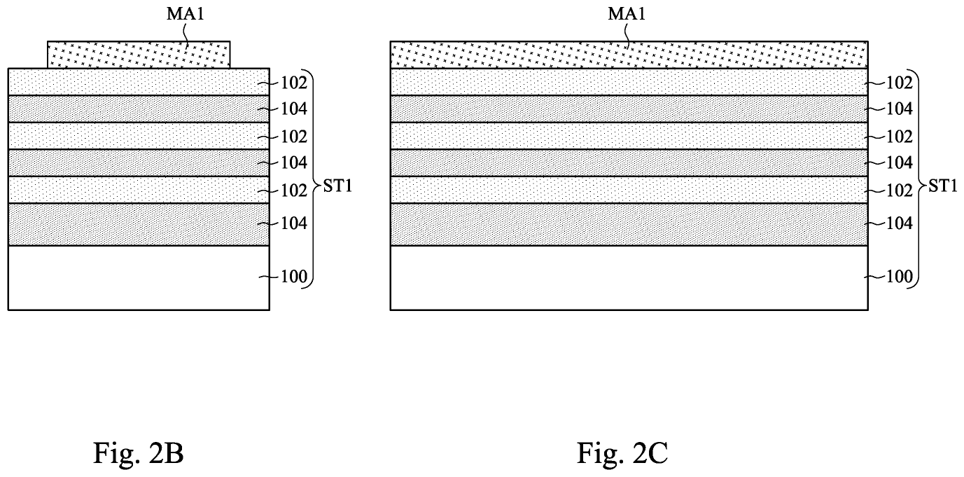

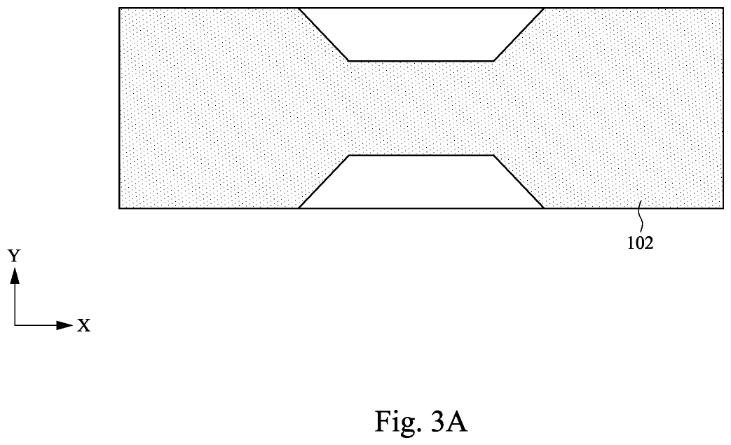

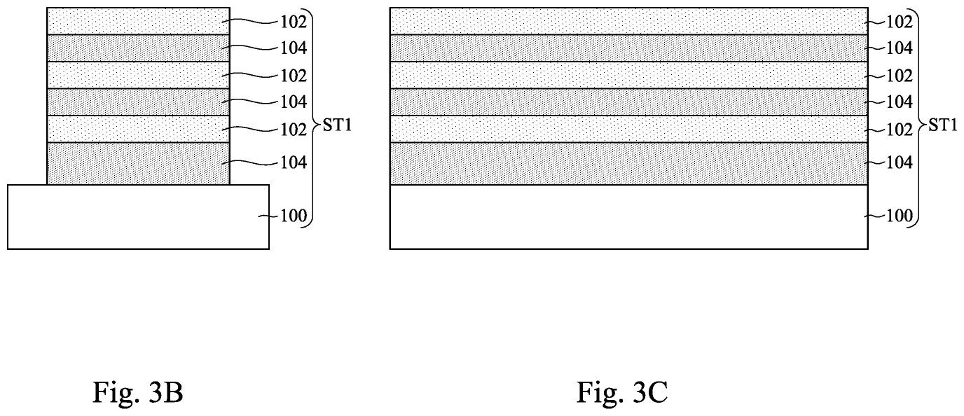

Reference is made to FIGS. 2A, 2B, and 2C. A patterned mask MA1 is formed over the substrate 100. The patterned mask MA1 may include openings that expose portions of the stack ST1, in which such portions will be removed in the following step (see FIGS. 3A to 3C). In some embodiments, the patterned mask MA1 may include photoresist or a hard mask (e.g., silicon nitride), and may be formed by suitable photolithography process.

Reference is made to FIGS. 3A, 3B, and 3C. Portions of the stack ST1 that are exposed through the openings of the patterned mask MA1 are removed. The removal process is performed to define the width of the channel region 102CH of the channel material layers 102 along a first direction (e.g., Y direction). In some embodiments, the portions of the stack ST1 may be removed using suitable etching process, such as wet etch, dry etch, combinations thereof, or the like. After the etching process is complete, the patterned mask MA1 may be removed.

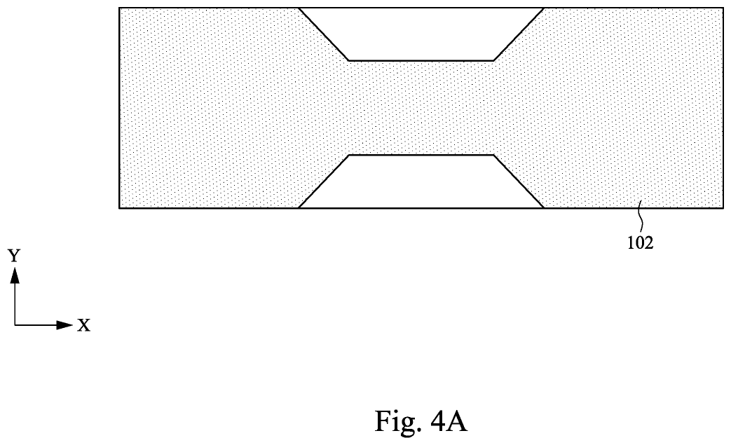

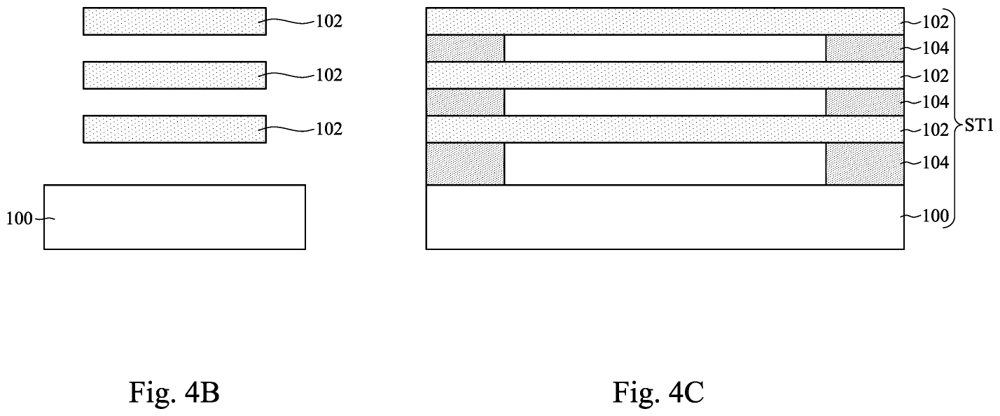

Reference is made to FIGS. 4A, 4B, and 4C. An etching process is performed to remove portions of the sacrificial layers 104. As a result, the channel regions 102CH of the channel material layers 102 are suspended over the substrate 100. On the other hand, portions of the sacrificial layers 104 that are between adjacent source/drain regions 102SD of the channel material layers 102 may remain after the etching process is complete, because such portions are protected by the source/drain regions 102SD of the channel material layers 102 having a larger area. In some embodiments, the topmost sacrificial layer 104 has been removed during the etching process. In some embodiments, the etching process may include wet etch, dry etch, combinations thereof, or the like. This process can also be referred to as “channel release process.”

After the channel release process is complete, an oxygen scavenging process may be performed to the source/drain regions 102SD of the channel material layers 102, so as to increase dopant concentration in the source/drain regions 102SD of the channel material layers 102. In greater detail, the oxygen scavenging process is performed to reduce oxygen atomic concentration of the source/drain regions 102SD of the channel material layers 102, so as to generate oxygen vacancies within the source/drain regions 102SD of the channel material layers 102. In some embodiments, the oxygen vacancies can also be regarded as dopants of the source/drain regions 102SD of the channel material layers 102. In some embodiments, the dopant concentration of the source/drain regions 102SD of the channel material layers 102 is higher than the dopant concentration of the channel regions 102CH of the channel material layers 102. That is, oxygen vacancies concentration of the source/drain regions 102SD of the channel material layers 102 is higher than the oxygen vacancies concentration of the channel regions 102CH of the channel material layers 102. Stated another way, oxygen concentration of the source/drain regions 102SD of the channel material layers 102 is lower than the oxygen concentration of the channel regions 102CH of the channel material layers 102. In some embodiments, the doped source/drain regions 102SD of the channel material layers 102 can be referred to as n-type doped regions.

In some embodiments where the channel material layers 102 include oxide semiconductor material, source/drain doped regions can be formed in the source/drain regions 102SD of the channel material layers 102 using the oxygen scavenging process. The oxygen scavenging process may be performed using the remaining portions of the sacrificial layers 104 as oxygen scavenging layers. For example, the sacrificial layers 104 may include a material (e.g., TiN, Ti-containing material, or the like) having higher stronger oxygen affinity than the channel material layers 102. The oxygen scavenging process can be conducted by performing an annealing process having a temperature in a range from about 25° C. to about 500° C. During the annealing process, oxygen atoms in the source/drain regions 102SD of the channel material layers 102 may be attracted by the remaining portions of the sacrificial layers 104, such that oxygen atoms in the source/drain regions 102SD of the channel material layers 102 may diffuse to the sacrificial layers 104, leaving oxygen vacancies in the source/drain regions 102SD of the channel material layers 102. On the other hand, because the portions of the sacrificial layers 104 are removed from the channel regions 102CH of the channel material layers 102, oxygen vacancies may not be formed in the channel regions 102CH of the channel material layers 102. That is, the channel regions 102CH of the channel material layers 102 may not be doped as a result of the annealing process. In some embodiments, the oxygen scavenging process as discussed in FIGS. 4A to 4C may be omitted.

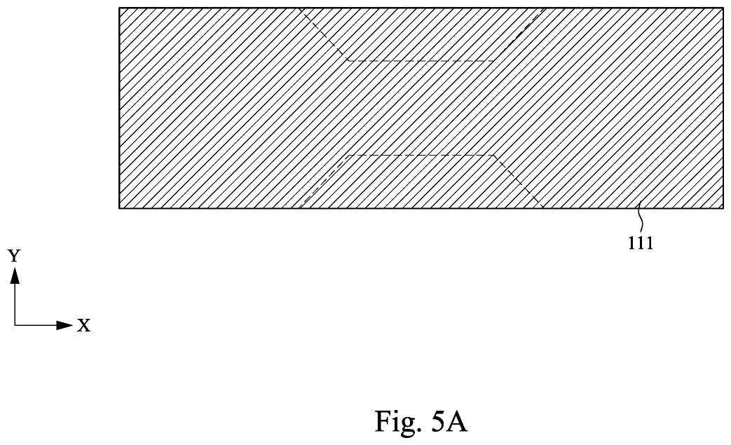

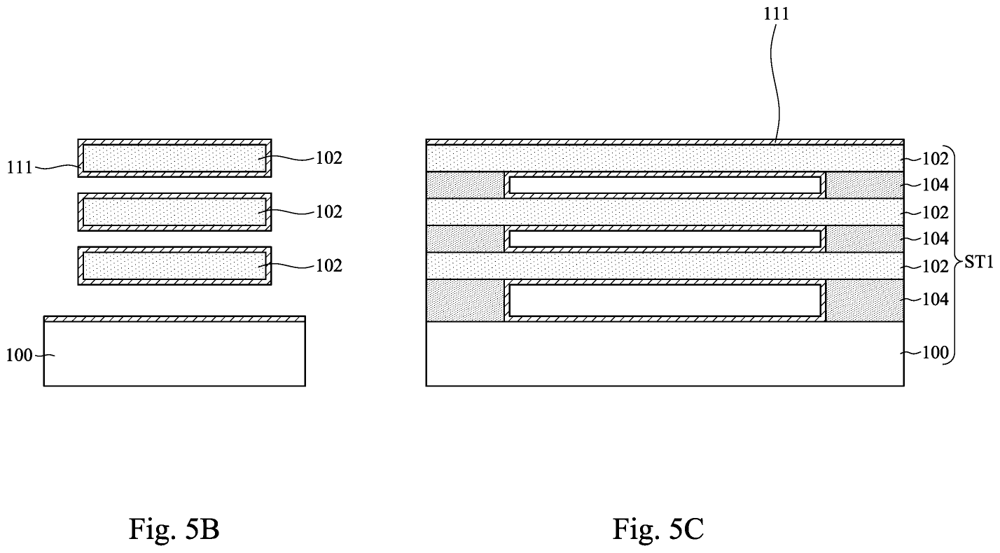

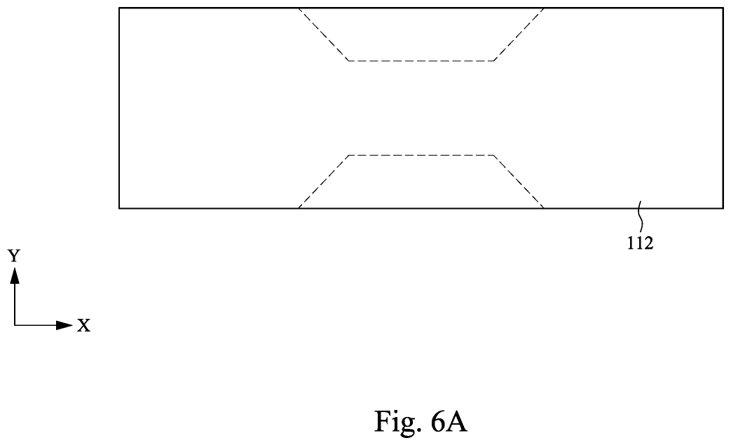

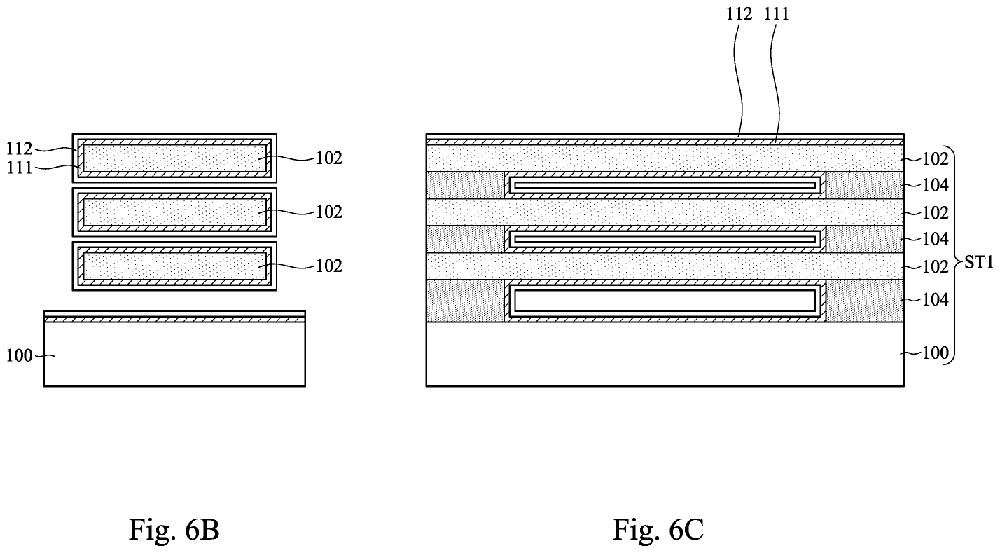

Reference is made to FIGS. 5A, 5B, and 5C. A barrier layer 111 is deposited over the substrate 100 and wraps around each of the channel regions 102CH of the channel material layers 102. As shown in the cross-sectional view of FIG. 6B, the barrier layer 111 may be in contact with at least four sides of each of the channel regions 102CH of the channel material layers 102. As shown in the cross-sectional view of FIG. 6C, the barrier layer 111 may be in contact with the sacrificial layers 104, and the barrier layer 111 may also include at least one portion having a rectangular ring shape cross-sectional profile. In some embodiments, the barrier layer 111 has a portion in contact with top surface of the substrate 100.

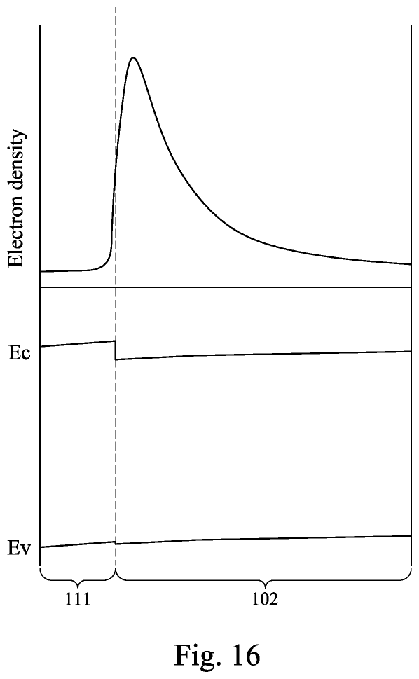

The barrier layer 111 may include a semiconductor material, such as an oxide semiconductor material. Examples of the oxide semiconductor material include indium gallium zinc oxide (IGZO), indium oxide (InOₓ), zinc oxide (ZnO), indium gallium oxide (IGO), indium zinc oxide (IZO), indium Gallium Zinc Tin Oxide (IGZTO), indium tin oxide (ITO), indium Gallium Tin Oxide (IGTO), or the like. As mentioned above, the channel material layers 102 may also be made of oxide semiconductor materials. The difference between the barrier layer 111 and the channel material layers 102 is that, the oxide semiconductor material of the barrier layer 111 is selected to have a higher conduction band value (E_{C}) than the oxide semiconductor material of the channel material layers 102. This can be done by varying combinations of indium (In), zinc (Zn), tin (Sn), gallium (Ga), and oxide (O) in the barrier layer 111, such that at least one of the indium (In), zinc (Zn), tin (Sn), gallium (Ga), and oxide (O) in the barrier layer 111 has a different concentration than that in the channel material layers 102. The conduction band value difference will result in carrier accumulation at the interface between the oxide semiconductor barrier layer 111 and oxide semiconductor channel material layers 102 during operation, which will be discussed in more detail in FIG. 16. The accumulated carriers will increase the carrier mobility of the oxide semiconductor channel material layers 102, and will further increase the ON current (I_{ON}) of the semiconductor device (e.g., the semiconductor device T1 in FIGS. 15A to 15C). However, if the barrier layer 111 is omitted, the gate dielectric layer 112 will be in direct contact with the oxide semiconductor channel material layers 102. Due to poor interface between gate dielectric layer and oxide semiconductor channel material layers, high trap density at the interface will result in coulomb scattering and the surface roughness scattering, and will deteriorate the device performance. In the present disclosure, a better interface quality between the barrier layer 111 and the channel material layers 102 will lead to reduction of the Coulomb scattering and the surface roughness scattering. Note that the barrier separates the traps in the gate dielectric layer 112 and the conduction electrons in the channel material layers 102 to reduce the Coulomb scattering. As a result, the device performance can be improved.

In some embodiments, the barrier layer 111 and the channel material layers 102 may include a same material (e.g., having same elements) but different in composition. For example, the barrier layer 111 and the channel material layers 102 both may include indium gallium zinc oxide (IGZO). However, the oxygen (O) concentration of the barrier layer 111 is higher than the oxygen concentration of the channel material layers 102. This is because higher oxygen concentration will increase the conduction band value of IGZO, and makes it a suitable material of the barrier layer 111.

In other embodiments, the barrier layer 111 and the channel material layers 102 may include different materials. For example, the barrier layer 111 may be made of indium gallium zinc oxide (IGZO), and the channel material layers 102 may include indium zinc oxide (IZO). Stated another way, the gallium (Ga) concentration of the barrier layer 111 is higher than the gallium concentration of the channel material layers 102. This is because higher gallium concentration will increase the conduction band value of IGZO, and makes it a suitable material of the barrier layer 111. The channel material layers 102 may also include indium gallium zinc oxide (IGZO), but with lower gallium concentration than the indium gallium zinc oxide (IGZO) of the barrier layer 111.

In other embodiments, the channel material layers 102 may be made of indium oxide (In₂O₃), and the barrier layer 111 is made of indium gallium zinc oxide (IGZO). That is, the barrier layer 111 may include higher gallium concentration and/or zinc concentration than the channel material layers 102. This is because the zinc and gallium are incorporated into the In₂O₃ will result in the increase of the band gap (as well as the conduction band value).

In some embodiments, the barrier layer 111 is deposited using a conformal deposition process, such as ALD, CVD, or the like. In some embodiments, the thickness of the barrier layer 111 is in a range from about 1 nm to about 1000 nm. If the barrier layer 111 is too thin (e.g., much less than 1 nm), current leakage may occur due to carrier tunneling from the channel material layers 102 to the barrier layer 111. If the barrier layer 111 is too thick (e.g., much greater than 1000 nm), there is no significant improvement for the device. In some embodiments, the barrier layer 111 is thinner than each of the channel material layers 102.

Reference is made to FIGS. 6A, 6B, and 6C. A gate dielectric layer 112 is deposited over the substrate 100 and covering the barrier layer 111. In some embodiments, the gate dielectric layer 112 is deposited using a conformal deposition process, such as ALD, CVD, or the like. In some embodiments, the thickness of the gate dielectric layer 112 is in a range from about 1 nm to about 1000 nm.

In some embodiments, the gate dielectric layer 112 may be made of a high-k dielectric material. Examples of high-k dielectric material include aluminum oxide (Al₂O₃), hafnium oxide (HfO₂), titanium oxide (TiO₂), zirconium oxide (ZrO₂), other suitable high-k dielectric materials, and/or combinations thereof. In other embodiments, the gate dielectric layer 112 may be made of a ferroelectric (FE) material. Examples of ferroelectric material layer may be or include hafnium zirconium oxide (HfZrO), hafnium aluminum oxide (HfAlO), zirconium oxide (ZrO), hafnium oxide (HfO) doped with lanthanum (La), silicon (Si), gadolinium (Gd), aluminum (Al), or the like, undoped hafnium oxide (HfO), lead zirconate titanate (PZT), strontium bismuth tantalate (SBT), or a combination thereof.

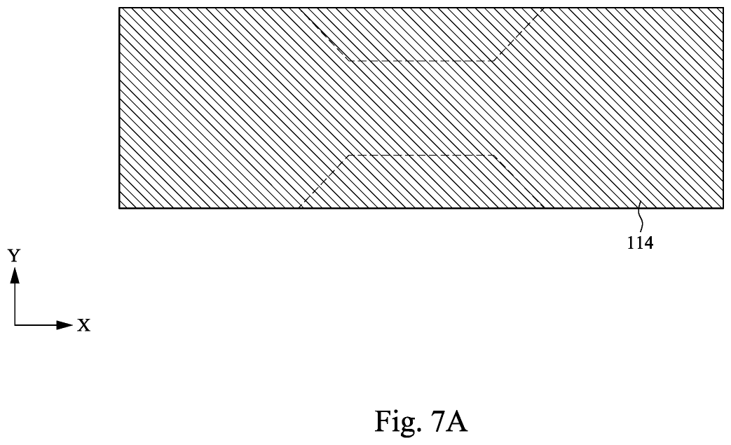

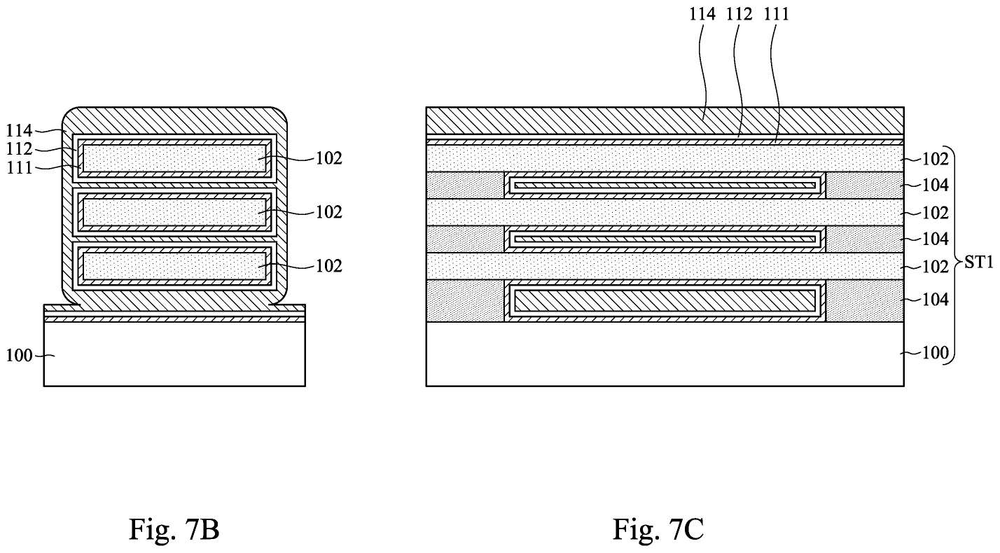

Reference is made to FIGS. 7A, 7B, and 7C. A first gate metal 114 is deposited over the substrate 100 and covering the gate dielectric layer 112. As shown in the cross-sectional view of FIG. 7B, the first gate metal 114 may be deposited filling the spaces between adjacent two of the channel material layers 102. Similarly, the first gate metal 114 may wrap around each of the channel regions 102CH of the channel material layers 102. In some embodiments, the first gate metal 114 may include titanium nitride (TiN), aluminum (Al), titanium (Ti), or the like. In some embodiments, the first gate metal 114 is deposited using a conformal deposition process, such as ALD, CVD, or the like. In some embodiments, the thickness of the first gate metal 114 is in a range from about 1 nm to about 1000 nm.

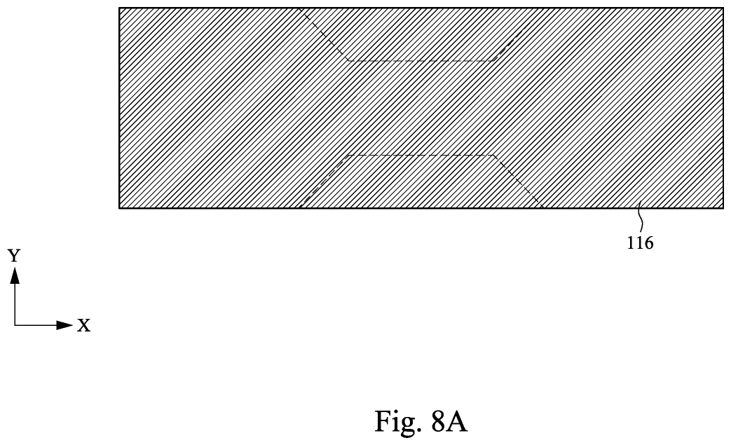

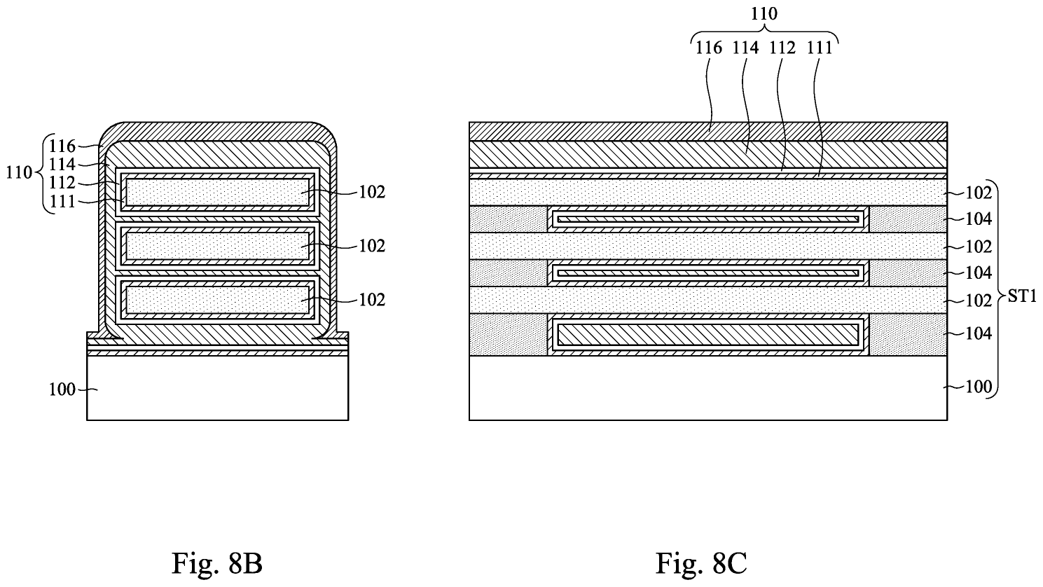

Reference is made to FIGS. 8A, 8B, and 8C. A second gate metal 116 is deposited over the substrate 100 and covering the first gate metal 114. The gate dielectric layer 112, the first gate metal 114, and second gate metal 116 may collectively be referred to as a gate structure 110. In some embodiments, the second gate metal 116 may include titanium nitride (TiN), tungsten (W), aluminum (Al), titanium (Ti), nickel (Ni), or the like. In some embodiments, the first gate metal 114 and the second gate metal 116 may include different materials to achieve desired work function value. In other embodiments, the first gate metal 114 and the second gate metal 116 may include a same material, while the first gate metal 114 and the second gate metal 116 are deposited using different deposition process. For example, the first gate metal 114 may be deposited using a conformal deposition process, such as ALD, CVD, or the like. The second gate metal 116 may be deposited using ALD, CVD, or sputtering. In some embodiments, the deposition process of the first gate metal 114 is performed such that the first gate metal 114 is able to warp around the channel material layers 102. The deposition process of the second gate metal 116 is performed to achieve a desired thickness of gate metal. In some embodiments, the thickness of the second gate metal 116 is in a range from about 1 nm to about 1000 nm.

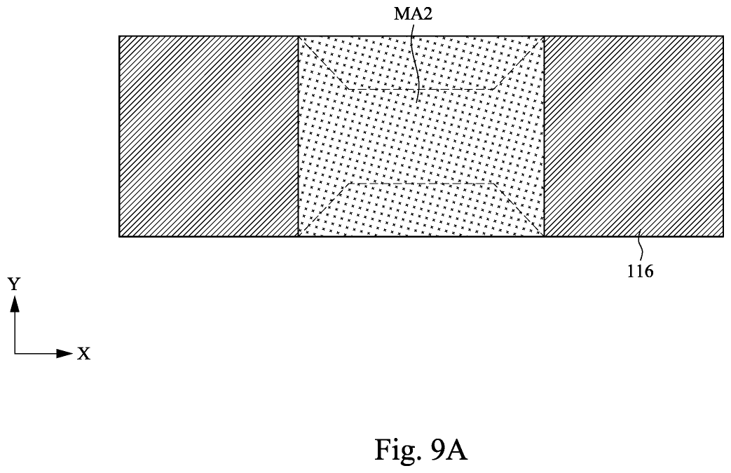

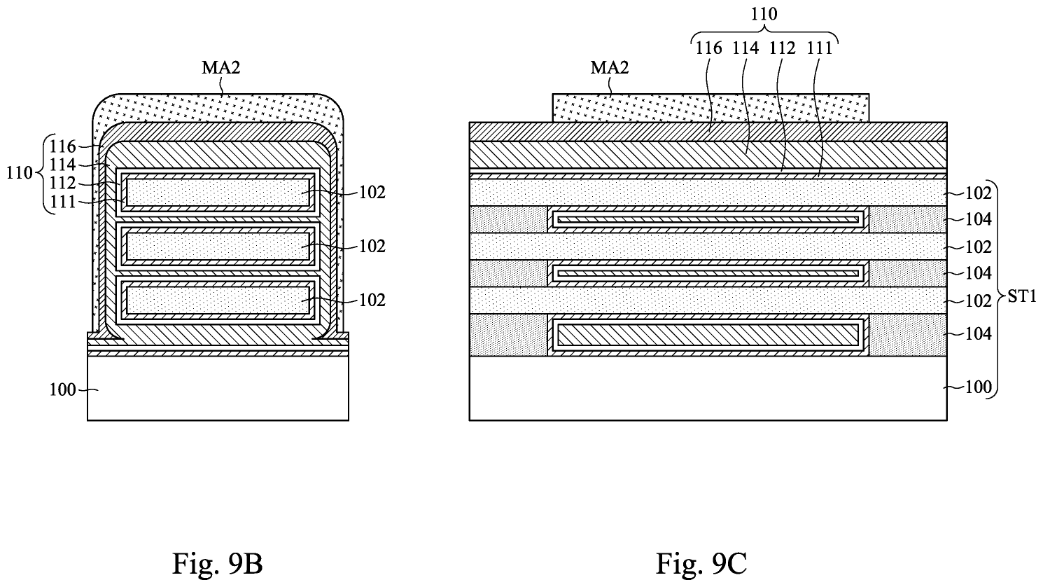

Reference is made to FIGS. 9A, 9B, and 9C. A patterned mask MA2 is formed over the substrate 100. In greater detail, as shown in FIG. 9C, the patterned mask MA2 overlaps the channel regions 102CH of the channel material layers 102 along the vertical direction. The patterned mask MA3 may include openings that expose portions of the stack ST1. Specifically, in FIG. 9C, the opening of the patterned mask MA3 may overlap the source/drain regions 102SD of the channel material layers 102 along the vertical direction. In some embodiments, the patterned mask MA2 may include photoresist or a hard mask (e.g., silicon nitride), and may be formed by suitable photolithography process.

Reference is made to FIGS. 10A, 10B, and 10C. Portions of the gate structure 110 overlapping the source/drain regions 102SD of the channel material layers 102 are removed. In greater detail, the portions of the barrier layer 111, the gate dielectric layer 112, the first gate metal 114, and the second gate metal 116 overlapping the source/drain regions 102SD of the channel material layers 102 are removed. As a result, the remaining portion of the gate structure 110 overlaps and wraps around each of the channel regions 102CH of the channel material layers 102. In some embodiments, the portions of the gate structure 110 may be removed using suitable etching process, such as wet etch, dry etch, combinations thereof, or the like. After the etching process is complete, the topmost channel material layer 102 is exposed.

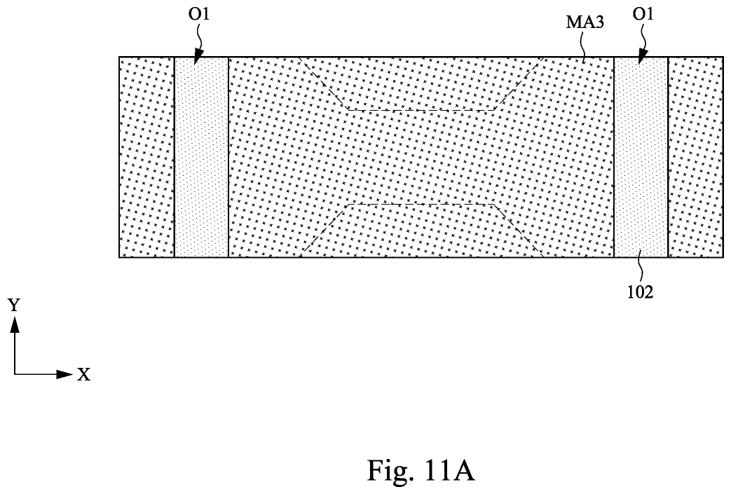

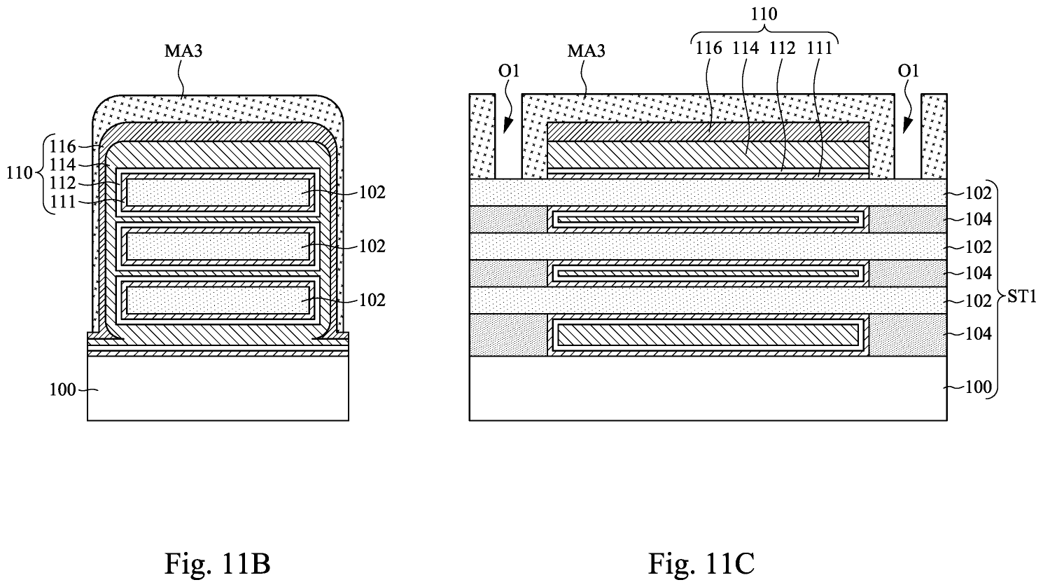

Reference is made to FIGS. 11A, 11B, and 11C. A patterned mask MA3 is formed over the substrate 100. In greater detail, as shown in FIG. 11C, the patterned mask MA3 may include openings O1 that expose portions of the stack ST1. Specifically, in FIG. 11C, the openings O1 of the patterned mask MA3 may overlap the source/drain regions 102SD of the channel material layers 102 along the vertical direction. In some embodiments, the patterned mask MA3 may include photoresist or a hard mask (e.g., silicon nitride), and may be formed by suitable photolithography process.

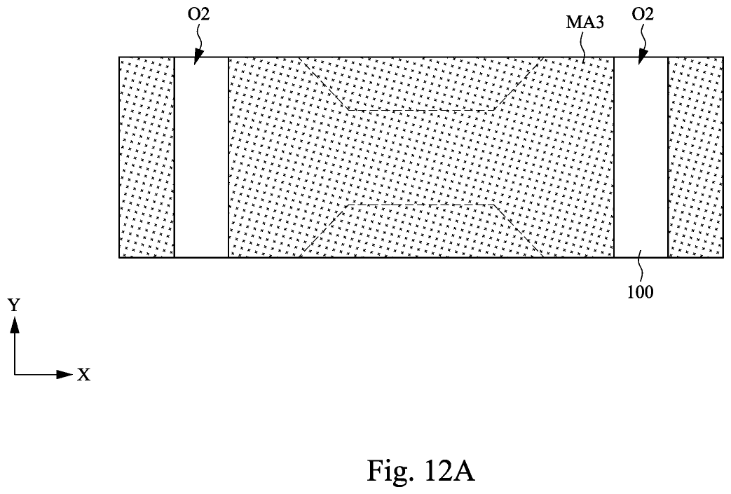

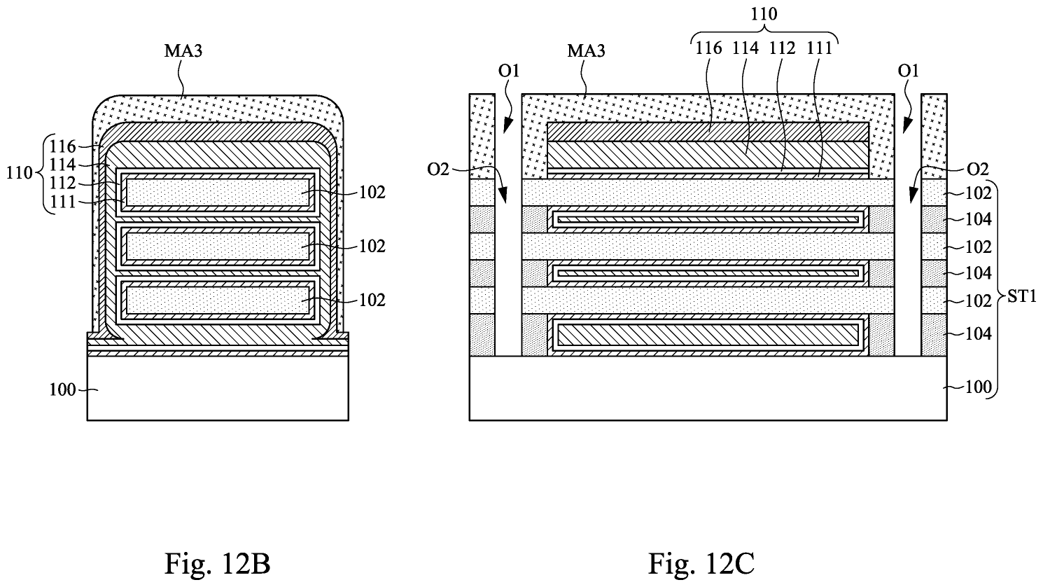

Reference is made to FIGS. 12A, 12B, and 12C. An etching process is performed by using the patterned mask MA3 as etching mask, so as to remove portions of the channel material layers 102 and the sacrificial layers 104 that are exposed through the openings O1. As a result, source/drain openings O2 are formed in the stack ST1. In some embodiments, the etching process may include wet etch, dry etch, combinations thereof, or the like. As shown in FIG. 12C, after the etching process is complete, portions of the sacrificial layers 104 remain on opposite sidewalls of the gate structure 110. The remaining portions of the sacrificial layers 104 may act as inner spacers, and can also be referred to as inner spacers 104 in the following content.

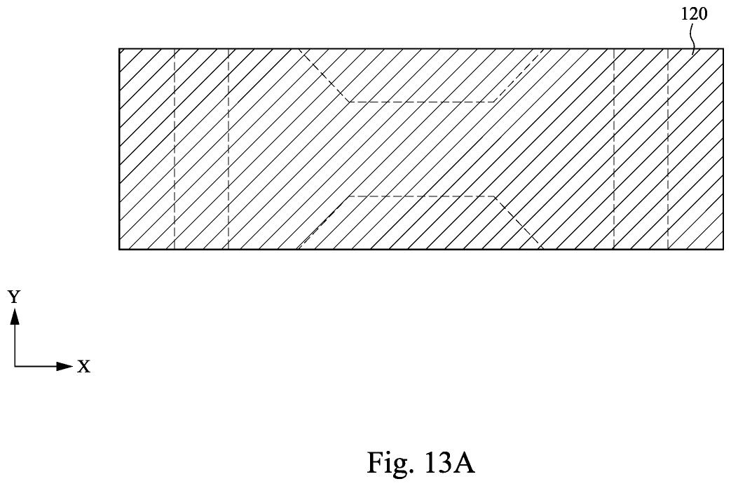

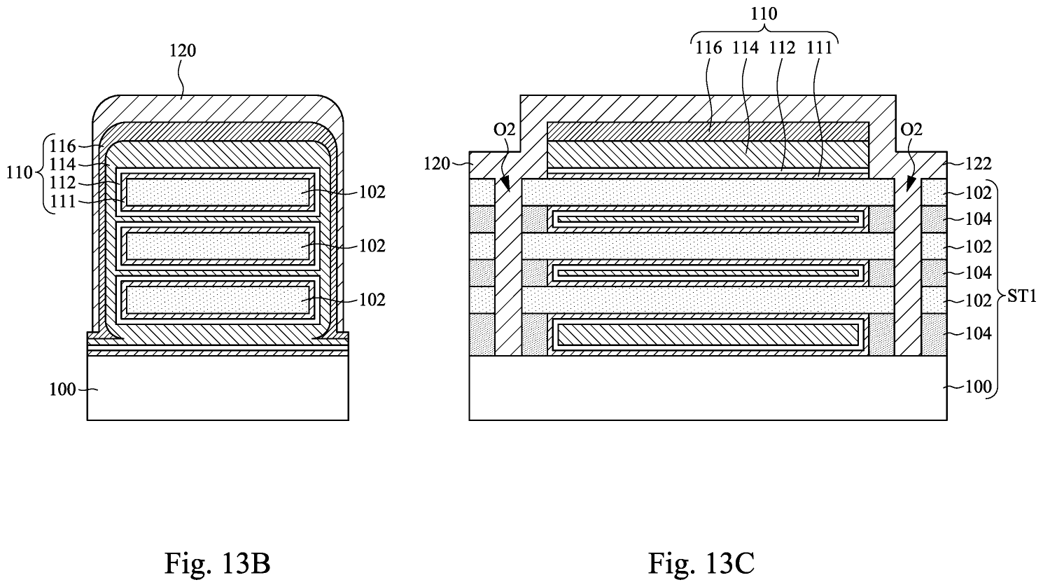

Reference is made to FIGS. 13A, 13B, and 13C. The patterned mask MA3 is removed. A conductive layer 120 is then deposited over the substrate 100 and filling the source/drain openings O2 in the stack ST1. In greater detail, the conductive layer 120 has portions in the source/drain openings O2 and in contact with the inner spacers 104 and the source/drain regions 102SD of the channel material layers 102. The conductive layer 120 also includes a portion lining sidewalls and top surface of the gate structure 110. In some embodiments, the conductive layer 120 may include titanium nitride (TiN), aluminum (Al), titanium (Ti), or the like. In some embodiments, the conductive layer 120 may be formed using a conformal deposition process, such as ALD, CVD, or the like. In some embodiments, the thickness of the conductive layer 120 is in a range from about 1 nm to about 1000 nm.

As mentioned above, the oxygen scavenging process as discussed in FIGS. 4A to 4C may be omitted. Instead, an oxygen scavenging process can be performed after the conductive layer 120 is formed. The oxygen scavenging process is performed to the source/drain regions 102SD of the channel material layers 102, so as to increase dopant concentration in the source/drain regions 102SD of the channel material layers 102. It is noted that in FIG. 13C, the source/drain regions 102SD of the channel material layers 102 may be the portions of the channel material layers 102 vertically overlapping with the inner spacers 104. In greater detail, the oxygen scavenging process is performed to reduce oxygen atomic concentration of the source/drain regions 102SD of the channel material layers 102, so as to generate oxygen vacancies within the source/drain regions 102SD of the channel material layers 102. In some embodiments, the oxygen vacancies can also be regarded as dopants of the source/drain regions 102SD of the channel material layers 102.

In some embodiments where the channel material layers 102 include oxide semiconductor material, source/drain doped regions can be formed in the source/drain regions 102SD of the channel material layers 102 using the oxygen scavenging process. The oxygen scavenging process may be performed using the source/drain electrodes 122 as oxygen scavenging layers. For example, the conductive layer 120 may include a material (e.g., TiN, Ti-containing material, or the like) having higher stronger oxygen affinity than the channel material layers 102. During the annealing process, oxygen atoms in the source/drain regions 102SD of the channel material layers 102 may be attracted by the conductive layer 120, such that oxygen atoms in the source/drain regions 102SD of the channel material layers 102 may diffuse to the conductive layer 120, leaving oxygen vacancies in the source/drain regions 102SD of the channel material layers 102.

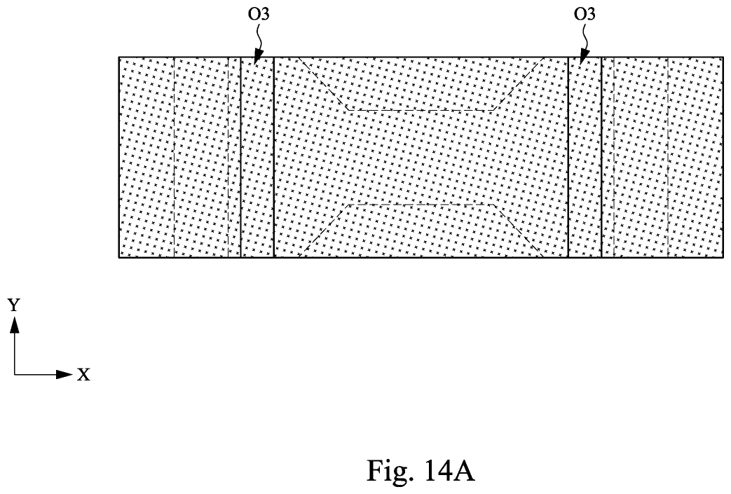

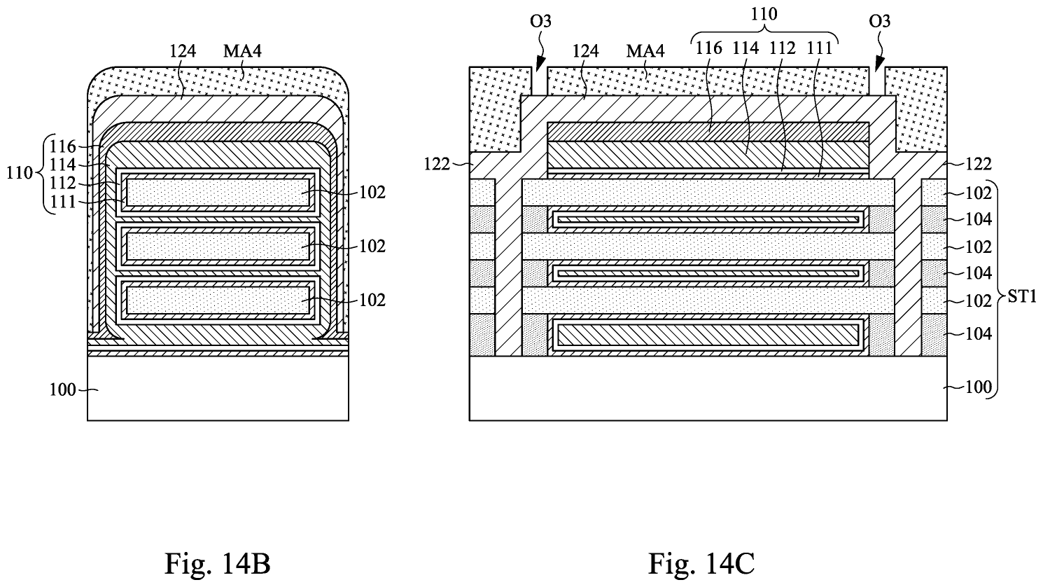

Reference is made to FIGS. 14A, 14B, and 14C. A patterned mask MA4 is formed over the substrate 100. In greater detail, as shown in FIG. 14C, the patterned mask MA4 may include openings O3 that expose portions of the conductive layer 120. Specifically, in FIG. 14C, the openings O3 of the patterned mask MA4 may overlap with the inner spacers 104 along the vertical direction. In some embodiments, the patterned mask MA4 may include photoresist or a hard mask (e.g., silicon nitride), and may be formed by suitable photolithography process.

Reference is made to FIGS. 15A, 15B, and 15C. An etching process is performed to remove portions of the conductive layer 120 exposed through the openings O3 of the patterned mask MA4. After the etching process is complete, the patterned mask MA4 is removed. Accordingly, the portions of the conductive layer 120 in contact with the source/drain regions 102SD of the channel material layers 102 are referred to as source/drain electrodes 122, and the portion of the conductive layer 120 in contact with gate structure 110 is referred to as gate electrode 124, in which the source/drain electrodes 122 and the gate electrode 124 are physically spaced apart from each other.

A semiconductor device T1 is then formed. The semiconductor device T1 may include the channel material layers 102, a gate structure 110 wrapping around the channel region 102CH of each of the channel material layers 102, source/drain electrodes 122 in contact with source/drain regions 102SD of each of the channel material layers 102, and a gate electrode 124 in contact with the gate structure 110. In some embodiments, the semiconductor device T1 can be a field effect transistor (FET). In some embodiments where the gate dielectric layer 112 of the gate structure 110 is made of a ferroelectric material, the semiconductor device T1 can be a ferroelectric field effect transistor (FeFET).

FIG. 16 illustrates a simulation result of a semiconductor device in accordance with some embodiments of the present disclosure. In the bottom of FIG. 16, band diagrams of the barrier layer 111 and the channel material layer 102 are shown where suitable gate voltage (V_{GS}) and drain voltage (V_{DS}) are applied. It is noted that E_{C} denotes to conduction band and Ev denotes to valence band, respectively. It can be seen that a conduction band discontinuity happens at the interface between the barrier layer 111 and the channel material layer 102, and electrons may accumulate at a local low-energy-level region near the interface. As also can be seen in the top of FIG. 16, the electrons may include higher density near the interface between the barrier layer 111 and the channel material layer 102. As mentioned above, the accumulated electrons will increase the carrier mobility of the oxide semiconductor channel material layers 102, and will further increase the ON current (I_{ON}) of the semiconductor device (e.g., the semiconductor device T1 in FIGS. 15A to 15C). This is because a better interface quality between the barrier layer 111 and the channel material layers 102 will lead to reduction of the Coulomb scattering and the surface roughness scattering. As a result, the device performance can be improved.

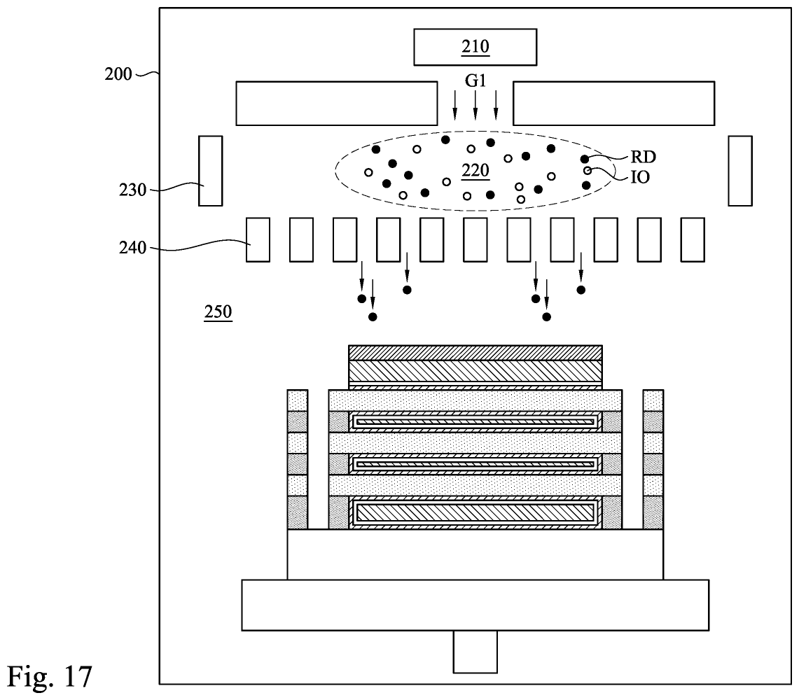

FIG. 17 illustrates a method of forming a semiconductor device in accordance with some embodiments of the present disclosure. In greater detail, FIG. 17 illustrates forming doped regions in the source/drain regions 102SD of the channel material layers 102 through the openings O2 (see FIG. 12C) using a highly selective isotropic dry etching (HiSIDE) method. In such embodiments, the oxygen scavenging process discussed in FIGS. 1A to 15C may be omitted.

During the HiSIDE method, the patterned mask MA3 of FIGS. 12A to 12C is removed, and the substrate 100 including the structures formed thereon is transferred to a plasma chamber 200. The plasma chamber 200 includes a gas source 210, a plasma generation region 220 in gaseous communication with the gas source 210, a radio frequency (RF) power source 230 adjacent to the plasma generation region 220, an ion filter 240 below the plasma generation region 220, and a reaction chamber 250 below the ion filter 240. The substrate 100 is transferred to the reaction chamber 250 and is supported by a substrate stage.

During the doping process, a gas G1 is supplied into the plasma generation region 220. At the same time, the RF power source 230 may be turn on, so as to generate ion plasma IO and radical plasma RD. In some embodiments, the gas G1 may be fluorine (F)-containing gas, such as nitrogen fluoride (NF₃). The RF power source 230 is configured to generate fluorine ion plasma (F⁻) and fluorine radical plasma (F*). On the other hand, the gas G1 may be hydrogen (H)-containing gas, such as hydrogen gas (H₂). The RF power source 230 is configured to generate hydrogen ion plasma (H⁺) and hydrogen radical plasma (H*). Here, the term “ion” may be referred to as atom or molecule that has a net charge. On the other hand, the term “radical” may be referred to as atom or molecule that has neutral charge.

During the doping process, the ion filter 240 is applied, so as to block certain types of ions in the plasma generation region 220 from entering the reaction chamber 250. The blocking is selective according to ion type. The Ion filter 240 can be operated through electrical or magnetic fields. In some embodiments, the ion filter 240 includes a DC power supply having a variable voltage. For example, when the ion plasma IO and radical plasma RD are fluorine ion plasma (F⁻) and fluorine radical plasma (F*), respectively, the ion filter 240 may be operated to generate a positive electrical field to attract the fluorine ion plasma (F⁻), and thus the attracted fluorine ion plasma (F⁻) is forbidden to enter the reaction chamber 250. On the other hand, the fluorine radical plasma (F*), which is neutral, is able to enter the reaction chamber 250. In some embodiments, when the ion plasma IO and radical plasma RD are hydrogen ion plasma (H⁺) and hydrogen radical plasma (H*), respectively, the ion filter 240 may be operated to generate a negative electrical field to attract the hydrogen ion plasma (H⁺), and thus the attracted hydrogen ion plasma (H⁺) is forbidden to enter the reaction chamber 250. On the other hand, the hydrogen radical plasma (H*), which is neutral, is able to enter the reaction chamber 250.

As shown in the figure, the source/drain regions 102SD of the channel material layers 102 are exposed to the radical plasma RD entering the reaction chamber 250. In some embodiments where the channel material layers 102 is made of oxide semiconductor material, the radical plasma RD may act as donor for the source/drain regions 102SD of the channel material layers 102. For example, when the radical plasma RD includes fluorine radical plasma (F*), the source/drain regions 102SD of the channel material layers 102 may be doped with fluorine, and thus the fluorine atomic concentration of the source/drain regions 102SD of the channel material layers 102 may be higher than the fluorine atomic concentration of the channel regions 102CH of the channel material layers 102. On the other hand, when the radical plasma RD includes hydrogen radical plasma (H*), the source/drain regions 102SD of the channel material layers 102 may be doped with hydrogen, and thus the hydrogen atomic concentration of the source/drain regions 102SD of the channel material layers 102 may be higher than the hydrogen atomic concentration of the channel regions 102CH of the channel material layers 102.

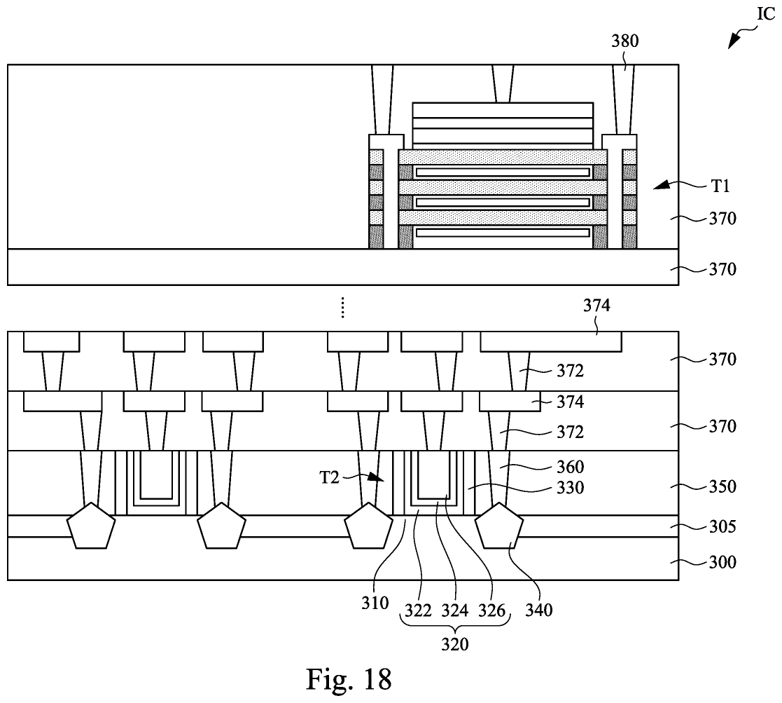

FIG. 18 illustrates a cross-sectional view of an integrated circuit in accordance with some embodiments of the present disclosure. Shown there is an integrated circuit IC. It is noted that some elements of FIG. 18 are similar to those described with respect to FIGS. 1A to 15C, and relevant details will not be repeated for brevity.

The integrated circuit IC includes a substrate 300. Generally, the substrate 300 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

The integrated circuit IC further includes semiconductor fins 310 protruding from top surface of the substrate 300. In some embodiments, the semiconductor fins 310 a same material as the substrate 300, or may include a different material than the substrate 300.

Isolation structures 305, such as shallow trench isolation structures (STI), are disposed over the substrate 300 and laterally surround the semiconductor fins 310. In some embodiments, the isolation structures 305 may include dielectric material such as silicon oxide, silicon nitride, the like, or combinations thereof.

Gate structures 320 are formed over the respective semiconductor fins 310. Each of the gate structures 320 may include a gate dielectric layer 322, a work function metal layer 324 over the gate dielectric layer 322, and a filling metal 326 over the work function metal layer 324.

In some embodiments, gate dielectric layer 322 may include an interfacial layer and a high-k dielectric layer over the interfacial layer. The interfacial layer may be made of oxide, such as aluminum oxide (Al₂O₃), silicon oxide (SiO₂), or the like. The high-k dielectric layer may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The work function metal layer 324 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal 326 may include tungsten (W), aluminum (Al), copper (Cu), or another suitable conductive material(s).

Gate spacers 330 are formed on opposite sidewalls of each of the gate structure 320. In some embodiments, the gate spacers 330 may include one or more dielectrics, such as silicon oxide, silicon nitride, silicon oxynitride, silicon carbide, silicon carbonitride, the like, or a combination thereof.

Source/drain regions 340 are formed over the semiconductor fins 310 and on opposite sides of each of the gate structures 320. In some embodiments, the source/drain regions 340 may include heavily-doped regions and relatively lightly-doped drain extensions, or LDD regions. The source/drain regions 340 may be formed, for example, by implanting dopants (e.g., As, P, B, In, or the like) using an ion implantation process.

The source/drain regions 340 may include an epitaxially grown region. For example, the semiconductor fins 310 may be first to form recesses therein, a crystalline semiconductor material may be deposited in the recesses by a selective epitaxial growth (SEG) process. The crystalline semiconductor material may be elemental (e.g., Si, or Ge, or the like), or an alloy (e.g., Si₁₋ₓCₓ, or Si₁₋ₓGeₓ, or the like). A high dose of dopants may be introduced into the source/drain regions 340 either in situ during SEG, or by an ion implantation process performed after the SEG, or by a combination thereof.

An interlayer dielectric (ILD) layer 350 is formed over the substrate 300, covering the source/drain regions 340 and laterally surrounding the gate structure 320. In some embodiments, the ILD layer 350 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Source/drain contacts 360 may be formed in the ILD layer 350 and electrically connected to the respective source/drain regions 340. The source/drain contacts 360 may include a conductive liner and a contact plug over the conductive liner. In some embodiments, the conductive liner may include Ti, Ni, Pt, Co, TiN, TaN, Ta, or other suitable metals. The contact plug may include tungsten (W) or other suitable conductive materials, such as Al, Cu, Ru, Ni, Co, alloys of these, combinations thereof, and the like.

The semiconductor fin 310, the gate structure 320 over the semiconductor fin 310, and the source/drain regions 340 may collectively serve as a semiconductor device T2, such as a transistor. The semiconductor device T2, the ILD layer 350, and the source/drain contacts 360 can be collectively referred to as a front-end-of-line (FEOL) structure.

The integrated circuit IC further includes an interconnect structure. The interconnect structure may include a plurality of metallization layers stacked one above another. In some embodiments, each metallization layer may include an inter-metal dielectric (IMD) layer 370. Conductive vias 372 and conductive lines 374 are disposed in the IMD layer 370.

The semiconductor device T1 as discussed in FIGS. 1A to 15C may be formed over an IMD layer 370. Another IMD layer 370 may be formed covering the semiconductor device T1. Conductive vias 380 are formed in the IMD layer 370 and electrically connected with the semiconductor device T1. The interconnect structure and the semiconductor device T1 can be referred to as a back-end-of-line (BEOL) structure. In some embodiments, the semiconductor device T1 at the BEOL structure may be electrically connected to the semiconductor devices T2 at the FEOL structure through the interconnect structure.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a semiconductor device by forming an oxide semiconductor barrier over an oxide semiconductor channel layer. During operation of the semiconductor device, carrier accumulation occurs at the interface between the oxide semiconductor barrier and the oxide semiconductor channel layer. The accumulated carriers will increase the carrier mobility of the oxide semiconductor channel layer, and will further increase the ON current (I_{ON}) of the semiconductor device. A better interface quality between the oxide semiconductor barrier and the oxide semiconductor channel layer will lead to reduction of the Coulomb scattering and the surface roughness scattering. As a result, the device performance can be improved.

In some embodiments of the present disclosure, a semiconductor device includes a substrate. An oxide semiconductor channel layer is over the substrate. A gate structure is over the oxide semiconductor channel layer. The gate structure includes an oxide semiconductor barrier layer over the oxide semiconductor channel layer, a gate dielectric layer over the oxide semiconductor barrier layer, and a gate metal over the gate dielectric layer. Source/drain electrodes are in contact with opposite ends of the oxide semiconductor channel layer.

In some embodiments, the oxide semiconductor channel layer and the oxide semiconductor barrier layer are different in composition.

In some embodiments, a material of the oxide semiconductor barrier layer has a higher conduction band value than a material of the oxide semiconductor channel layer.

In some embodiments, the oxide semiconductor barrier layer wraps around the oxide semiconductor channel layer in a cross-sectional view.

In some embodiments, the semiconductor device further includes spacers on opposite sides of the gate structure, wherein the oxide semiconductor barrier layer are in contact with the spacers.

In some embodiments, the oxide semiconductor channel layer and the oxide semiconductor barrier layer are made of indium gallium zinc oxide (IGZO), and an oxygen concentration of the oxide semiconductor barrier layer is higher than an oxygen concentration of the oxide semiconductor channel layer.

In some embodiments, the oxide semiconductor barrier layer is made of indium gallium zinc oxide (IGZO), and the oxide semiconductor channel layer is made of indium zinc oxide (IZO).

In some embodiments of the present disclosure, a semiconductor device includes a substrate. A semiconductive channel layer is over the substrate. A gate structure is over the semiconductive channel layer. The gate structure includes a semiconductive barrier layer wrapping around the semiconductive channel layer, a gate dielectric layer over the semiconductive barrier layer, a gate metal over the gate dielectric layer. A material of the semiconductive barrier layer has a higher conduction band value than a material of the semiconductive channel layer. Source/drain electrodes are in contact with opposite ends of the semiconductive channel layer.

In some embodiments, the semiconductive barrier layer is made of a first oxide semiconductor material.

In some embodiments, the semiconductive channel layer is made of a second oxide semiconductor material.

In some embodiments, the gate dielectric layer is made of a high-k dielectric material.

In some embodiments, the gate dielectric layer is made of a a ferroelectric material.

In some embodiments, the semiconductive channel layer is thicker than the semiconductive barrier layer.

In some embodiments, the semiconductive barrier layer has a higher oxygen concentration than the semiconductive channel layer.

In some embodiments, the semiconductive barrier layer has a higher germanium concentration than the semiconductive channel layer.

In some embodiments of the present disclosure, a method includes forming a stack of alternating oxide semiconductor channel layers and sacrificial layers over a substrate; removing portions of the sacrificial layers such that channel regions of the oxide semiconductor channel layers are suspended over the substrate; forming an oxide semiconductor barrier layer wrapping around the channel regions of the oxide semiconductor channel layers; forming a gate dielectric layer over the oxide semiconductor barrier layer; and forming a gate metal over the gate dielectric layer.

In some embodiments, the oxide semiconductor channel layers and the oxide semiconductor barrier layer are different in composition.

In some embodiments, a material of the oxide semiconductor barrier layer has a higher conduction band value than a material of the oxide semiconductor channel layer.

In some embodiments, the oxide semiconductor barrier layer extends to a top surface of the substrate.

In some embodiments, the method further includes forming source/drain electrodes on opposite ends of the oxide semiconductor channel layers, wherein the source/drain electrodes are in contact with remaining portions of the sacrificial layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
an oxide semiconductor channel layer over the substrate;
a gate structure over the oxide semiconductor channel layer and comprising:
an oxide semiconductor barrier layer over the oxide semiconductor channel layer;
a gate dielectric layer over the oxide semiconductor barrier layer; and
a gate metal over the gate dielectric layer; and
source/drain electrodes in contact with opposite ends of the oxide semiconductor channel layer.

2. The semiconductor device of claim 1, wherein the oxide semiconductor channel layer and the oxide semiconductor barrier layer are different in composition.

3. The semiconductor device of claim 1, wherein a material of the oxide semiconductor barrier layer has a higher conduction band value than a material of the oxide semiconductor channel layer.

4. The semiconductor device of claim 1, wherein the oxide semiconductor barrier layer wraps around the oxide semiconductor channel layer in a cross-sectional view.

5. The semiconductor device of claim 1, further comprising spacers on opposite sides of the gate structure, wherein the oxide semiconductor barrier layer are in contact with the spacers.

6. The semiconductor device of claim 1, wherein the oxide semiconductor channel layer and the oxide semiconductor barrier layer are made of indium gallium zinc oxide (IGZO), and an oxygen concentration of the oxide semiconductor barrier layer is higher than an oxygen concentration of the oxide semiconductor channel layer.

7. The semiconductor device of claim 1, wherein the oxide semiconductor barrier layer is made of indium gallium zinc oxide (IGZO), and the oxide semiconductor channel layer is made of indium oxide (InO).

8. A semiconductor device, comprising:
a substrate;
a semiconductive channel layer over the substrate;
a gate structure over the semiconductive channel layer and comprising:
a semiconductive barrier layer wrapping around the semiconductive channel layer, wherein a material of the semiconductive barrier layer has a higher conduction band value than a material of the semiconductive channel layer;
a gate dielectric layer over the semiconductive barrier layer; and
a gate metal over the gate dielectric layer; and
source/drain electrodes in contact with opposite ends of the semiconductive channel layer.

9. The semiconductor device of claim 8, wherein the semiconductive barrier layer is made of a first oxide semiconductor material.

10. The semiconductor device of claim 9, wherein the semiconductive channel layer is made of a second oxide semiconductor material.

11. The semiconductor device of claim 8, wherein the gate dielectric layer is made of a high-k dielectric material.

12. The semiconductor device of claim 8, wherein the gate dielectric layer is made of a a ferroelectric material.

13. The semiconductor device of claim 8, wherein the semiconductive channel layer is thicker than the semiconductive barrier layer.

14. The semiconductor device of claim 8, wherein the semiconductive barrier layer has a higher oxygen concentration than the semiconductive channel layer.

15. The semiconductor device of claim 8, wherein the semiconductive barrier layer has a higher gallium concentration or a higher zinc concentration than the semiconductive channel layer.

16. A method, comprising:
forming a stack of alternating oxide semiconductor channel layers and sacrificial layers over a substrate;
removing portions of the sacrificial layers such that channel regions of the oxide semiconductor channel layers are suspended over the substrate;
forming an oxide semiconductor barrier layer wrapping around the channel regions of the oxide semiconductor channel layers;
forming a gate dielectric layer over the oxide semiconductor barrier layer; and
forming a gate metal over the gate dielectric layer.

17. The method of claim 16, wherein the oxide semiconductor channel layers and the oxide semiconductor barrier layer are different in composition.

18. The method of claim 16, wherein a material of the oxide semiconductor barrier layer has a higher conduction band value than a material of the oxide semiconductor channel layers.

19. The method of claim 16, wherein the oxide semiconductor barrier layer extends to a top surface of the substrate.

20. The method of claim 16, further comprising forming source/drain electrodes on opposite ends of the oxide semiconductor channel layers, wherein the source/drain electrodes are in contact with remaining portions of the sacrificial layers.
